(19) United States
(12) Patent Application Publication
(10) Pub. No.: US 2016/0276374 A1
(43) Pub. Date: Sep. 22, 2016

(54) Active Matrix Substrate, Display Apparatus and Manufacturing Method for Active Matrix Substrate

(71) Applicant: Sakai Display Products Corporation, Sakai-shi, Osaka (JP)

(72) Inventors: Nobutake NODERA, Sakai-shi, Osaka (JP); Akihiro SHINOZUKA, Sakai-shi, Osaka (JP); Shinji KOIWA, Sakai-shi, Osaka (JP); Masahiro KATO, Sakai-shi, Osaka (JP); Takao MATSUMOTO, Sakai-shi, Osaka (JP)

(21) Appl. No.: 15/031,974

(22) PCT Filed: Oct. 21, 2014
(86) PCT No.: PCT/JP2014/077985

§ 371 Date: Apr. 25, 2016

(30) Foreign Application Priority Data
Oct. 31, 2013 (JP) 2013-226246

(51) Int. Cl. H01L 27/12; G02F 1/1333; G02F 1/1335; G02F 1/1362; G02F 1/1368; G02F 1/1339

(52) U.S. Cl. CPC H01L 27/1248; H01L 27/124; H01L 27/1259; G02F 1/1368; G02F 1/1339; G02F 1/133514; G02F 1/136286; G02F 1/133345

(57) ABSTRACT

Provide are: an active matrix substrate with a preferable transmittance in which no by-product is generated because no resist is used and an interlayer insulating film is formed at low cost while the occurrence of a failure is suppressed and a favorable yield is obtained; a display apparatus; and a manufacturing method for the active matrix substrate.

A gate electrode and a capacitance wiring are formed on the insulating substrate in the active matrix substrate, and an interlayer insulating film is formed to cover the insulating substrate. On the gate electrode and the capacitance wiring, contact holes Ca and Cb are formed. A gate insulating film is formed on the interlayer insulating film, and a semiconductor film and an n⁺ film are formed on the portion on the gate insulating film corresponding to the contact hole Ca, each of which is provided with the source electrode and the drain electrode. The interlayer insulating film is made of an SOG material having photosensitivity, and is formed without using a resist.

### CROSS-REFERENCE TO RELATED APPLICATIONS

This application is the national phase under 35 U.S.C. §371 of PCT International Application No. PCT/JP2014/077985 which has an International filing date of Oct. 21, 2014 and designated the United States of America.

### BACKGROUND

1. Technical Field

The present invention relates to an active matrix substrate included in a television receiver, a personal computer and so forth, to a display apparatus including the active matrix substrate, and to a manufacturing method for the active matrix substrate.

2. Description of Related Art

Among display apparatuses, a liquid crystal display apparatus has characteristics of being thin and consuming a small amount of electricity. Specifically, a liquid crystal display apparatus comprising an active matrix substrate having a switching element such as a thin film transistor (TFT) or the like for each pixel presents high performance including high contrast ratio and good response characteristics, and is thus preferably used for a television receiver, a personal computer and so forth.

Multiple gate wirings (scanning wirings) and multiple source wirings (signal wirings) which cross the respective gate wirings through an interlayer insulating film are formed on the active matrix substrate. The thin film transistor for switching a pixel is provided near the crossing part of the gate wiring and the source wiring (see Japanese Patent Application Laid-Open No. 2008-153688, for example).

The capacitance (parasitic capacitance) formed at the crossing part of the gate wiring and the source wiring is preferably small as it may be a cause of degrading the display quality.

FIG. 15 is a schematic cross-sectional view illustrating an example of the structure of a portion of the conventional active matrix substrate 60 where a TFT 61 is formed.

As illustrated in FIG. 15, a gate electrode 11a (a part of a gate wiring 11) and a capacitance wiring 13 are formed on the insulating substrate 10 made of glass in an active matrix substrate 60.

The interlayer insulating film 14 is formed to cover the insulating substrate 10. The portion except for the respective edges on the gate electrode 11a and the capacitance wiring 13 is not covered by the interlayer insulating film 14. A contact hole Ca and a contact hole Cb are formed at the portion. A gate insulating film 15 is formed on the interlayer insulating film 14, and a semiconductor film 16 is formed at the portion on the interlayer insulating film 14 corresponding to the contact hole Ca. An n⁺ film 17 is formed so as to cover the semiconductor film 16, and a source region as well as a drain region is formed on which a source electrode 18 and a drain electrode 19 are formed. The gate electrode 11a, the gate insulating film 15, the semiconductor film 16, the n⁺ film 17, the source electrode 18 and the drain electrode 19 constitute a TFT 61.

A passivation film 21 is then formed so as to cover the source electrode 18 and the drain electrode 19, and an interlayer insulating film 22 containing an organic material is formed to cover the passivation film 21.

Furthermore, at the contact hole Cb, a capacitance electrode 20 is formed on the gate insulating film 15. A pixel electrode 23 is formed on the capacitance electrode 20.

FIG. 16 is a flowchart illustrating a processing procedure of forming the interlayer insulating film 14.

An SOG material is applied onto the insulating substrate 10, the gate wiring 11 and the capacitance wiring 13, to form a coating film (S11).

After forming the coating film, the film is baked and the thickness thereof is adjusted (S12).

After baking, a photoresist material is applied onto the coating film to form a resist. (S13)

The film is exposed to light using a photomask (S14) and is then developed (S15) to form a resist pattern.

Next, the part of the coating film not covered by the resist is undergone etching such as dry etching using mixed gas of tetrafluoromethane and oxygen (S16), to form the contact holes Ca and Cb.

Finally, the resist is removed (S17).

### SUMMARY

In the active matrix substrate such as the one in Japanese Patent Application Laid-Open No. 2008-153688 described above, when the interlayer insulating film 14 containing the SOG material is formed between the gate wiring 11 and the source wiring, the processes of applying a resist, etching and removing the resist are required to form the contact holes Ca and Cb, which poses a problem of increase in the initial cost of manufacturing.

Moreover, due to the by-product generated by etching, the rate of failure is increased and the yield is lowered, which further increases the initial cost. The by-product causes a leak between wirings, which leaves the interlayer insulating film 14 at parts other than the required portions. That is, the opening part of the interlayer insulating film 14 is limited to such parts as the portion where the TFT 61 is formed and the portion where the contact hole Cb is formed. The small area of the opening of the interlayer insulating film 14 causes lowering in the transmittance of a panel, which thus requires a backlight with high luminescence in order to compensate the low transmittance of the panel.

The present invention has been made in view of the circumstances. An object is to provide an active matrix substrate with a preferable transmittance in which an interlayer insulating film is formed at low cost in the state in which by-product is not generated because resist is not used so that the occurrence of a failure is suppressed and a favorable yield is obtained. And further object is to provide a display apparatus including the active matrix substrate and a manufacturing method for the active matrix substrate.

In an active matrix substrate according to one embodiment of the present invention in which, on a substrate, a plurality of source wirings and a plurality of gate wirings are formed to cross each other in different levels, a thin-film transistor is formed near a portion where the source wiring and the gate wiring cross each other, a pixel electrode is formed which is electrically connected to a corresponding one of the source wirings via the thin-film transistor, and an interlayer insulating film containing a spin-on-glass (SOG) material is interposed at least between the source wiring and the gate wiring, the SOG material is photosensitive.

According to the embodiment, when patterning after forming a film containing the SOG material with photosensitivity, the resist applying process, the etching process and the resist removing process are not required, which can lower the cost of manufacturing. As the etching process is eliminated, no by-product is generated, which lowers the occurrence of a failure and increases the yield.

In the active matrix substrate according to the embodiment of the present invention, it is preferable that the interlayer insulating film has a resistance to heat of 350° C. or higher, a light transmittance of 90% or higher, and a dielectric constant of 4 or lower.

According to the preferable embodiment, the active matrix substrate has a heat resistance to the thermal history when forming another film in a subsequent process. The light transmittance after receiving the thermal history is 90% or higher.

In the active matrix substrate according to the embodiment of the present invention, it is preferable that the interlayer insulating film is formed at a portion where the source wiring and the gate wiring cross each other.

According to the preferable embodiment, as an interlayer insulating film may be formed without the etching process, no abnormal substance is generated from the SOG material and the occurrence of a leak between wirings may be suppressed, so that an interlayer insulating film may be formed at a minimal part that requires lowering of the wiring capacitance at the crossing part of the gate wiring and the source wiring. Therefore, the active matrix substrate may be so designed that no interlayer insulating film is disposed at a pixel portion where the transmittance needs to be secured, at a capacitance wiring portion where the capacitance needs to be increased and at a contact hole portion, thereby allowing a display panel provided with the active matrix substrate to have a preferable transmittance.

In the active matrix substrate according to the embodiment of the present invention, it is preferable that the active matrix substrate further comprises an interlayer insulating film containing an SOG material with sensitivity over the thin-film transistor.

According to the preferable embodiment, the material for the film forming the active matrix substrate and the equipment for film deposition may be commonalized.

A display apparatus according to one embodiment of the present invention comprises: the active matrix substrate described above; a display medium layer arranged on the active matrix substrate; and an opposing substrate opposed to the active matrix substrate via the display medium layer.

In the embodiment, the display apparatus can have a preferable transmittance because the active matrix substrate described above is included therein.

In a method of manufacturing an active matrix substrate according to one embodiment of the present invention comprising processes of, on a substrate, forming a plurality of source wirings and a plurality of gate wirings to cross each other in different levels, forming a thin-film transistor near a portion where the source wiring and the gate wiring cross each other and forming a pixel electrode which is electrically connected to a corresponding one of the source wirings via the thin-film transistor, and comprising an interlayer insulating film forming process of forming an interlayer insulating film containing a spin-on-glass (SOG) material at least between the source wiring and the gate wiring, the interlayer insulating film forming process includes: a film forming process of forming a film using an SOG material with photosensitivity; a process of prebaking a formed film; a process of exposing a prebaked film to light; a process of developing an exposed film; and a process of baking a developed film.

According to the embodiment, when patterning after forming a film containing the SOG material with photosensitivity, the resist applying process, the etching process and the resist removing process are not required, which can lower the cost of manufacturing. As the etching process is eliminated, no by-product is generated, which lowers the occurrence of a failure and increases the yield.

In the method of manufacturing an active matrix substrate according to the embodiment of the present invention, it is preferable that the film forming process includes forming a film at a portion where the source wiring and the gate wiring cross each other.

According to the preferable embodiment, as an interlayer insulating film may be formed without the etching process, no abnormal substance is generated from the SOG material and the occurrence of a leak between wirings may be suppressed, so that an interlayer insulating film may be formed only at a minimal part that requires lowering of the wiring capacitance at the crossing part of the gate wiring and the source wiring. Therefore, the active matrix substrate may be so designed that no interlayer insulating film is disposed at a pixel portion where the transmittance needs to be secured, at a capacitance wiring portion where the capacitance needs to be increased and at a contact hole portion, thereby allowing a display panel provided with an active matrix substrate to have a preferable transmittance.

In the method of manufacturing an active matrix substrate according to the embodiment of the present invention, it is preferable that the SOG material contains at least two kinds of polysiloxanes with different rates of solubility to a tetramethylammonium hydroxide water solution, a diazonaphthoquinone derivative and a solvent.

According to the preferable embodiment, the SOG material has good photosensitivity and the interlayer insulating film has a preferable thermal resistance, transparency and insulation property.

According to the present invention, as the SOG material having photosensitivity is used, no resist is used so that no by-product is generated, which suppresses the occurrence of a failure while an interlayer insulating film may be formed at low cost and with a high yield as well as a preferable transmittance.

The above and further objects and features will more fully be apparent from the following detailed description with accompanying drawings.

### BRIEF DESCRIPTION OF THE SEVERAL VIEWS OF THE DRAWINGS

FIG. 1 is a schematic perspective view illustrating a television receiver according to Embodiment 1 of the present invention.

FIG. 2 is a schematic section view illustrating a display panel according to Embodiment 1 of the present invention.

FIG. 3 is a schematic plan view illustrating a pixel of an active matrix substrate according to Embodiment 1 of the present invention.

FIG. 4 is a schematic section view illustrating a portion of an active matrix substrate where a TFT is formed according to Embodiment 1 of the present invention.

FIG. 5 is a schematic section view illustrating a portion of an active matrix substrate where a gate wiring and a source wiring cross each other according to Embodiment 1 of the present invention.

FIG. 6A is a schematic section view illustrating a manufacturing process in a method of manufacturing an active matrix substrate according to Embodiment 1 of the present invention.

FIG. 6B is a schematic section view illustrating a manufacturing process in a method of manufacturing an active matrix substrate according to Embodiment 1 of the present invention.

FIG. 6C is a schematic section view illustrating a manufacturing process in a method of manufacturing an active matrix substrate according to Embodiment 1 of the present invention.

FIG. 6D is a schematic section view illustrating a manufacturing process in a method of manufacturing an active matrix substrate according to Embodiment 1 of the present invention.

FIG. 6E is a schematic section view illustrating a manufacturing process in a method of manufacturing an active matrix substrate according to Embodiment 1 of the present invention.

FIG. 7F is a schematic section view illustrating a manufacturing process in a method of manufacturing an active matrix substrate according to Embodiment 1 of the present invention.

FIG. 7G is a schematic section view illustrating a manufacturing process in a method of manufacturing an active matrix substrate according to Embodiment 1 of the present invention.

FIG. 7H is a schematic section view illustrating a manufacturing process in a method of manufacturing an active matrix substrate according to Embodiment 1 of the present invention.

FIG. 8 is a flowchart illustrating a processing procedure of forming an interlayer insulating film according to Embodiment 1 of the present invention.

FIG. 9 is a schematic section view illustrating a portion of an active matrix substrate where a TFT is formed according to Embodiment 2 of the present invention.

FIG. 10 is a schematic section view illustrating a portion of an active matrix substrate where a gate wiring and a source wiring cross each other according to Embodiment 2 of the present invention.

FIG. 11 is a schematic section view illustrating a portion of an active matrix substrate where a TFT is formed according to Embodiment 3 of the present invention.

FIG. 12 is a schematic section view illustrating a portion of an active matrix substrate where a TFT is formed according to Embodiment 4 of the present invention.

FIG. 13 is a schematic section view illustrating a portion of an active matrix substrate where a TFT is formed according to Embodiment 5 of the present invention.

FIG. 14 is a schematic section view illustrating a portion of an active matrix substrate where a gate wiring and a source wiring cross each other according to Embodiment 5 of the present invention.

FIG. 15 is a schematic cross-sectional view illustrating an example of the structure of a portion of the conventional active matrix substrate where a TFT is formed.

FIG. 16 is a flowchart illustrating a processing procedure of forming the conventional interlayer insulating film.

### DETAILED DESCRIPTION

Embodiments of the present invention will be described below in detail with reference to the drawings illustrating the embodiments thereof.

### Embodiment 1

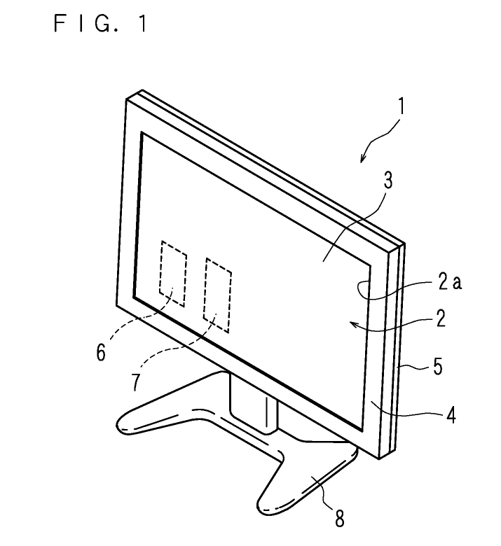

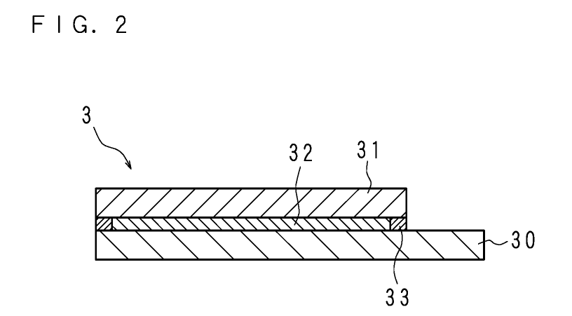

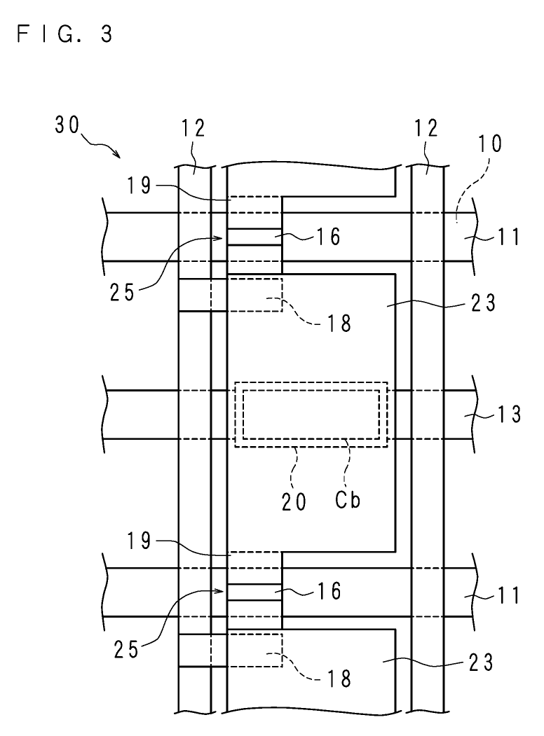

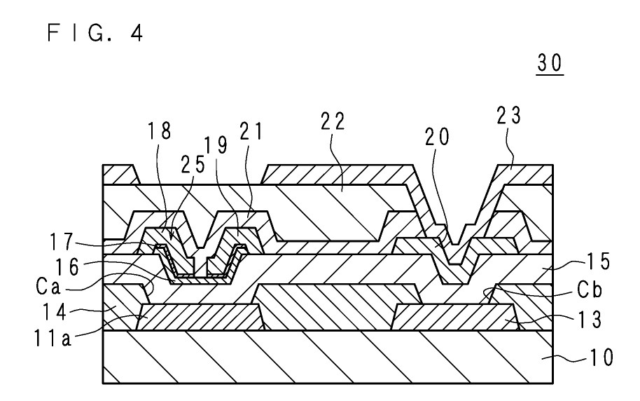

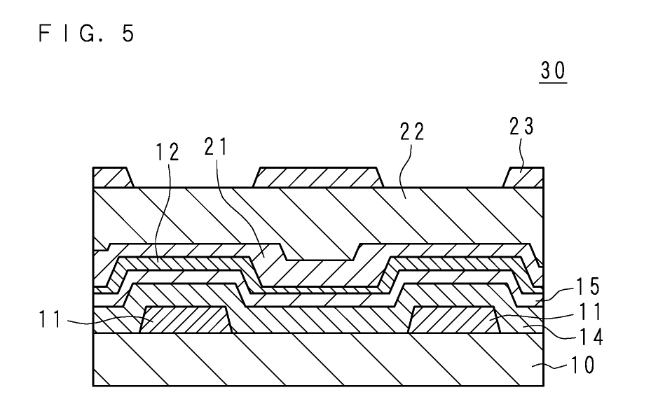

FIG. 1 is a schematic perspective view illustrating a television receiver (hereinafter referred to as a TV receiver) 1 according to Embodiment 1 of the present invention, FIG. 2 is a schematic section view illustrating a display panel 3 according to Embodiment 1, FIG. 3 is a schematic plan view illustrating a pixel of an active matrix substrate 30 according to Embodiment 1, FIG. 4 is a schematic section view illustrating a portion of the active matrix substrate 30 where a TFT 25 is formed, and FIG. 5 is a schematic section view illustrating a portion of the active matrix substrate 30 where a gate wiring 11 and a source wiring 12 cross each other.

The TV receiver 1 comprises a horizontally-long display module 2 on which an image is displayed, a tuner 6 which receives broadcast waves from an antenna (not depicted) and a decoder 7 which decodes coded broadcast waves. The TV receiver 1 decodes at the decoder 7 the broadcast waves received by the tuner 6, and displays an image on the display module 2 based on the decoded information. At the lower part of the TV receiver 1, a stand 8 is provided for supporting the TV receiver 1.

The display module 2 comprises, when it is an edge light type for example, a display panel 3 as well as, e.g., three optical sheets, and though not illustrated, a light guide plate, a reflection sheet and a chassis.

The display module 2 is accommodated with a vertical attitude inside a front cabinet 4 and a rear cabinet 5 that are vertically arranged at the front and rear respectively. The front cabinet 4 is a rectangular frame body covering the circumferential part of the display module 2 and has a rectangular opening 2a in the middle thereof. The front cabinet 4 is made of, for example, a plastic material. The rear cabinet 5 has a rectangular tray shape with its front side opened, and is made of, for example, a plastic material. It is noted that the front cabinet 4 and the rear cabinet 5 may be made of another material.

The front cabinet 4 has substantially the same vertical and horizontal dimensions as those of the rear cabinet 5, while the respective circumferential parts thereof are opposed to each other. The vertical and horizontal dimensions of the display panel 3 are slightly larger than those of the opening 2a of the front cabinet 4, while the circumferential part of the display panel 3 is opposed to the inner circumferential part of the front cabinet 4.

The display panel 3 comprises: an active matrix substrate 30 and an opposing substrate (color filter substrate) 31 that are opposed to each other; a liquid crystal layer 32 formed as a display medium layer between the active matrix substrate 30 and the opposing substrate 31; and a seal material 33 of a frame shape so provided as to bond the active matrix substrate 30 to the opposing substrate 31 while enclosing the liquid crystal layer 32 between the active matrix substrate 30 and the opposing substrate 31.

As illustrated in FIG. 3, the active matrix substrate 30 comprises: multiple gate wirings 11 provided to extend in parallel with each other on an insulating substrate 10 such as a glass substrate; multiple capacitance wirings 13 provided between each of the gate wirings 11 to extend in parallel with each other; multiple source wirings 12 provided to extend in parallel with each other in a direction crossing the respective gate wirings 11; multiple TFTs 25 provided for each crossing part of the gate wiring 11 and the source wiring 12, i.e., for each pixel; multiple pixel electrodes 23 connected to the TFTs 25, respectively; and an alignment film (not depicted) formed to cover each pixel electrode 23.

As illustrated in FIG. 5, at the crossing part of the gate wiring 11 and the source wiring 12 of the active matrix substrate 30, the interlayer insulating film 14 and the gate insulating film 15 are interposed between the gate wiring 11 and the source wiring 12 formed on the insulating substrate 10.

The interlayer insulating film 14 is made of an SOG material having photosensitivity as will be described later.

The SOG material with photosensitivity is a material having heat resistance to the thermal history in the subsequent process, and such a material is used that will not change in its property when subjected to thermal history in the deposition process for the gate insulating film 15, for example. To withstand the thermal history in the deposition process for the gate insulating film 15, the material preferably has a resistance to heat of 350° C. Moreover, the interlayer insulating film 14 may preferably have the transmittance of 90% or higher even when subjected to the thermal history described above. Furthermore, the interlayer insulating film 14 may preferably have a dielectric constant of 4 or lower.

A passivation film 21 is then formed so as to cover the source wiring 12, and an interlayer insulating film 22 containing an organic material is formed to cover and to planarize the passivation film 21. The pattern of a pixel electrode 23 is formed on the interlayer insulating film 22.

As illustrated in FIG. 4, a gate electrode 11a (which forms a part of the gate wiring 11) and a capacitance wiring 13 are formed on the insulating substrate 10 in the active matrix substrate 30.

The interlayer insulating film 14 is so formed as to cover the insulating substrate 10. The portions except for the respective edges on the gate electrode 11a and the capacitance wiring 13 is not covered by the interlayer insulating film 14. A contact hole Ca and a contact hole Cb are formed at the portions. A gate insulating film 15 is formed on the interlayer insulating film 14, the gate electrode 11a and the capacitance wiring 13, and a semiconductor film 16 is formed at the portion on the gate insulating film 15 corresponding to the contact hole Ca. An n⁺ film 17 is formed so as to cover the semiconductor film 16, and a source region as well as a drain region is formed, on which a source electrode 18 and a drain electrode 19 are formed. The gate electrode 11a, the gate insulating film 15, the semiconductor film 16, the n⁺ film 17, the source electrode 18 and the drain electrode 19 constitute a TFT 25.

A passivation film 21 is then formed so as to cover the source electrode 18 and the drain electrode 19, and an interlayer insulating film 22 is formed to cover the passivation film 21.

A capacitance electrode 20 is formed at a position corresponding to the capacitance wiring 13 on the gate insulating film 15. A pixel electrode 23 is formed on the capacitance electrode 20.

The pixel electrode 23 is connected to the capacitance electrode 20 at a portion corresponding to the contact hole Cb, and the capacitance electrode 20 is formed over the capacitance wiring 13 via the gate insulating film 15, so that the auxiliary capacitance is formed.

In the display panel 3, in each pixel, a gate signal is sent from a gate driver (not depicted) to the gate electrode 11a via the gate wiring 11, and when the TFT 25 is turned on, a source signal is sent from a source driver (not depicted) to the source electrode 18 via the source wiring 12, and a predetermined electric charge is written into the pixel electrode 23 via the semiconductor film 16 and the drain electrode 19. Here, a potential difference is caused between each pixel electrode 23 of the active matrix substrate 30 and a common electrode of the opposing substrate 31, and a predetermined voltage is applied to the liquid crystal layer 32, i.e., the liquid crystal capacitance of each pixel and to the auxiliary capacitance connected in parallel with the liquid crystal capacitance. Then, in each pixel of the display panel 3, the alignment state of the liquid crystal layer 32 is changed depending on the voltage applied to the liquid crystal layer 32, and an image is displayed while the light transmittance of the liquid crystal layer 32 is adjusted.

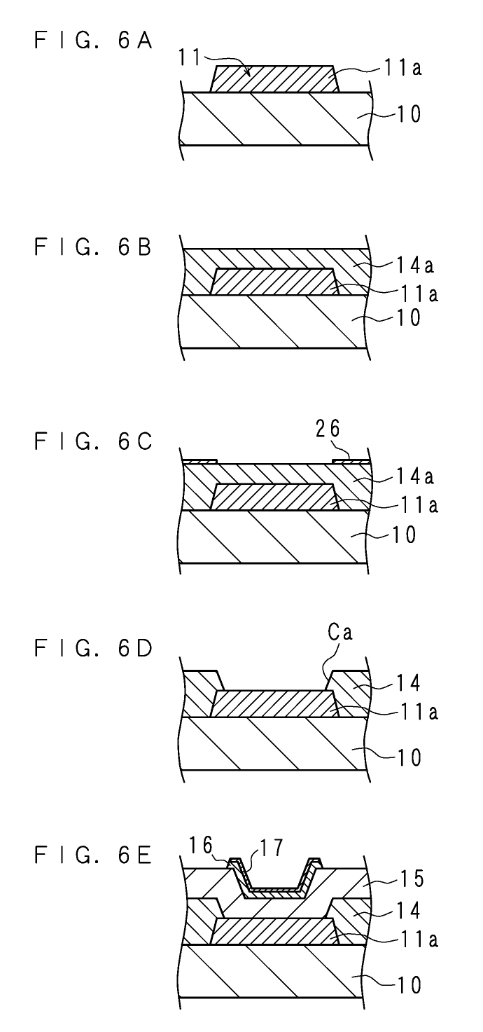

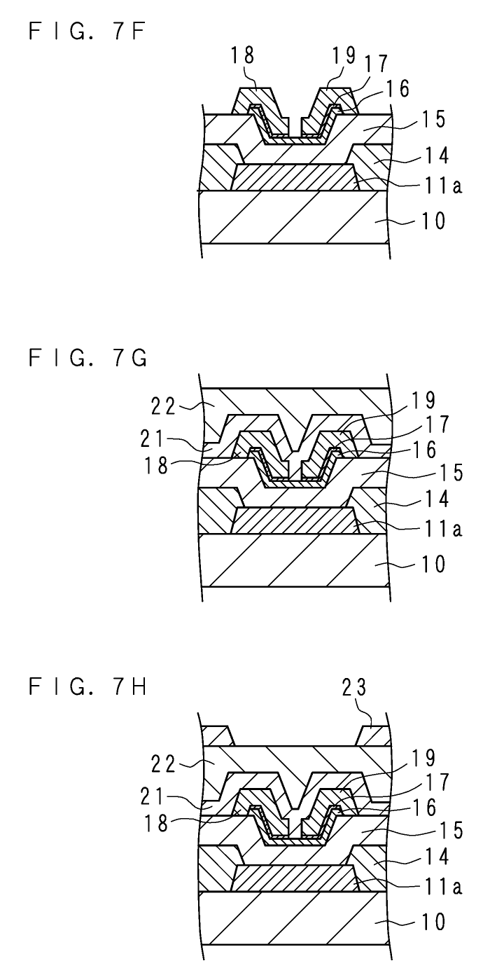

FIGS. 6 and 7 are schematic section views illustrating manufacturing processes in a method of manufacturing the active matrix substrate 30 according to the present embodiment.

First, a metal film in which, for example, a titanium film (with the thickness of approximately 50 nm), an aluminum film (with the thickness of approximately 200 nm) and a titanium film (with the thickness of approximately 100 nm) are laminated in this order is deposited on the entire insulating substrate 10 such as a glass substrate using the sputtering method, and then photolithography using a photomask, dry etching of the metal film, removal of a resist and washing are performed to form the gate wiring 11 (as well as the part constituting the gate electrode 11a) and the capacitance wiring 13 (FIG. 6A).

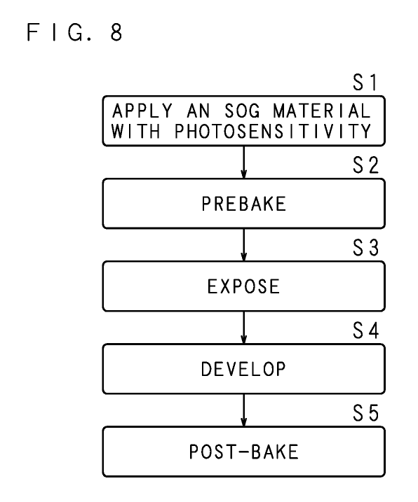

Subsequently, the interlayer insulating film 14 is formed (FIGS. 6B-D). FIG. 8 is a flowchart illustrating a processing procedure of forming the interlayer insulating film.

First, an SOG material with photosensitivity is applied onto the substrate 10 including the gate wiring 11 and the capacitance wiring 13 using a spin coating method, to form a film 14a (51, FIG. 6B).

Here, a composition containing at least two kinds of polysiloxanes with different rates of solubility to tetramethylammonium hydroxide (TMAH) water solution, a diazonaphthoquinone derivative and a solvent may be listed as the SOG material.

Additionally, the mixture of polysiloxane (I) and polysiloxane (II) described below, for example, may be listed as the two kinds of polysiloxanes.

For the polysiloxane (I), a post-prebake film that is obtained by hydrolysis and condensation of the silane compound represented by the following formula (1) and the silane compound represented by the following formula (2) under the presence of a basic catalyst is soluble to the 5 mass % TMAH solution, and the solubility thereof is 1,000 Å/sec or less.

RSi(OR¹)₃ (1)

Si(OR¹)₄ (2)

(In the formulas, R represents a straight-chain, branched or cyclic 1-20C alkyl group in which any methylene may be replaced by oxygen, or a 6-20C aryl group in which any hydrogen may be replaced by fluorine, and R¹ represents a 1-5C alkyl group.)

As a concrete example of the silane compound represented by the general formula (1), methyl trimethoxysilane, methyltriethoxysilane, phenyltrimethoxysilane, phenyltriethoxysilane, etc. may be listed.

As a concrete example of the silane compound represented by the general formula (2), a tetramethoxysilane, a tetraethoxysilane, etc. may be listed.

For polysiloxane (II), a solubility with respect to a 2.38 mass % TMAH solution of a post-prebake film that is obtained by hydrolysis and condensation of at least the silane compound represented by the general formula (1) under the presence of an acid or basic catalyst is 100 Å/sec or more.

After forming the film 14a, the film thickness is adjusted by prebaking for 90 seconds at 100° C., for example (S2).

After the prebaking, the film 14a is exposed to light through a photomask 26 (S3, FIG. 6C) and thereafter developed with a 2.38% TMAH solution (S4). Accordingly, a pattern from which the parts corresponding to the contact holes Ca, Cb and so forth are removed without any residue is formed.

Finally, the film 14a is post-baked at 250° C., for example, and is cured to obtain the interlayer insulating film 14 (S5, FIG. 6D).

A film of, for example, silicon oxide or silicon nitride is formed on the interlayer insulating film 14 using the Chemical Vapor Deposition (CVD) method and is patterned so that the gate insulating film 15 is formed.

Because of the thermal resistance to 350° C. or higher as described above, the physical property of the interlayer insulating film 14 remains unchanged even with the thermal history in the deposition process of the gate insulating film 15.

Subsequently, the CVD method is used, for example, to form a film made of amorphous silicon or the like and a film made of n⁺ amorphous silicon or the like, and the film is patterned so as to form the semiconductor film 16 and the n⁺ film 17 corresponding to the source region and the drain region (FIG. 6E).

Then, the sputtering method is used, for example, to deposit Mo or the like and patterning is performed, so that the source electrode 18 and the drain electrode 19 are formed on the source region and the drain region (FIG. 7F). Here, the capacitance electrode 20 (not depicted) is formed at the portion of the gate insulating film 15 corresponding to the contact hole Cb.

A film made of silicon nitride or the like is formed on the source electrode 18 and the drain electrode 19 using, for example, the CVD method and is then patterned to form a passivation film 21, and a film made of acrylic resin is formed on the passivation film 21 and is then patterned to form the interlayer insulating film 22 (FIG. 7G).

An ITO film is formed on the interlayer insulating film 22 using, for example, the sputtering method and is then patterned to form the pixel electrode 23 (FIG. 7H).

According to the present embodiment, when forming a pattern including the contact holes Ca and Cb after forming the film 14a containing the SOG material with photosensitivity, the resist applying process, the etching process and the resist removing process are not required, which can lower the cost of manufacturing. As the etching process is eliminated, no by-product (abnormal substance) is generated and no leak between wirings occurs, which lowers the occurrence of a failure and increases the yield.

The interlayer insulating film 14 has a transmittance of 90% or higher, and thus the display panel 3 comprising the active matrix substrate 30 having the interlayer insulating film 14 has a preferable transmittance.

### Embodiment 2

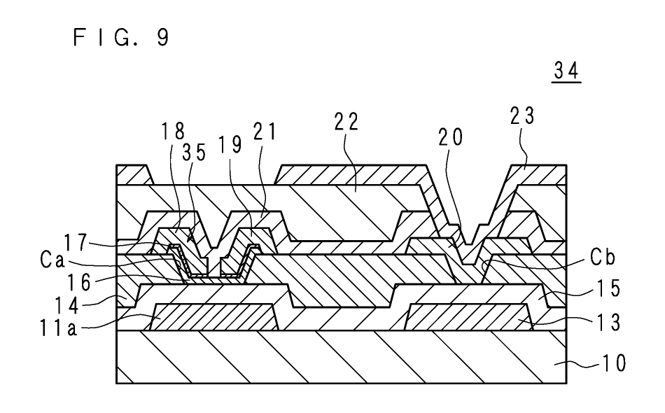

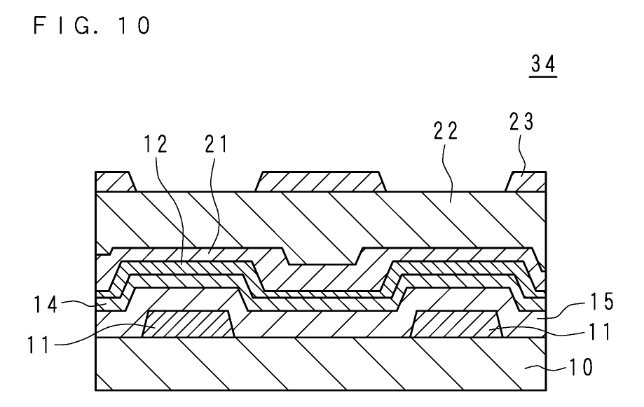

The display module according to Embodiment 2 of the present invention has the same configuration as the display module 2 according to Embodiment 1, except for the different order of deposition of the interlayer insulating film 14 and the gate insulating film 15 on an active matrix substrate 34. FIG. 9 is a schematic section view illustrating a portion of the active matrix substrate 34 where a TFT 35 is formed, and FIG. 10 is a schematic section view illustrating a portion of the active matrix substrate 34 where the gate wiring 11 and the source wiring 12 cross each other. In FIGS. 9 and 10, the same portions as those in FIGS. 4 and 5 are denoted by the same reference codes and will not be described in detail.

As illustrated in FIG. 10, at the crossing part of the gate wiring 11 and the source wiring 12 on the active matrix substrate 34, the gate insulating film 15 and the interlayer insulating film 14 are interposed in this order from the insulating substrate 10 side between the gate wiring 11 and the source wiring 12 formed on the insulating substrate 10.

The interlayer insulating film 14 is made of an SOG material having photosensitivity similar to that described above.

As illustrated in FIG. 9, the gate electrode 11a and the capacitance wiring 13 are formed on the insulating substrate 10 in the active matrix substrate 34.

The gate insulating film 15 is formed to cover the insulating substrate 10, the gate wiring 11 including the gate electrode 11a and the capacitance wiring 13. The interlayer insulating film 14 is formed to cover the gate insulating film 15. At the portions of the interlayer insulating film 14 corresponding to the gate electrode 11a and the capacitance wiring 13, a contact hole Ca and a contact hole Cb are formed. In the contact hole Ca of the interlayer insulating film 14, the semiconductor film 16 and the n⁺ film 17 are formed in this order.

According to the present embodiment, when patterning after forming the film 14a containing the SOG material with photosensitivity, the resist applying process, the etching process and the resist removing process are not required, which can lower the cost of manufacturing. As the etching process is eliminated, no by-product is generated and no leak between wirings is generated, which lowers the occurrence of a failure and increases the yield.

The interlayer insulating film 14 has a transmittance of 90% or higher, and thus the display panel 3 has a preferable transmittance.

### Embodiment 3

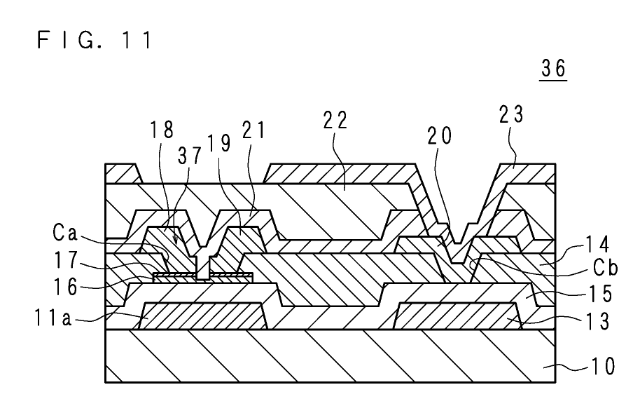

A display apparatus according to Embodiment 3 of the present invention has the same configuration as the display apparatus according to Embodiment 2, except that the interlayer insulating film 14 is formed after forming the semiconductor film 16 and the n⁺ film 17 on an active matrix substrate 36. FIG. 11 is a schematic section view illustrating a portion of the active matrix substrate 36 where a TFT 37 is formed. In the active matrix substrate 36, the portion where the gate wiring 11 and the source wiring 12 cross each other has the same configuration as the configuration of the portion where the gate wiring 11 and the source wiring 12 cross each other according to Embodiment 2. In FIG. 11, the same portions as those in FIG. 9 are denoted by the same reference codes and will not be described in detail.

As illustrated in FIG. 11, the gate electrode 11a and the capacitance wiring 13 are formed on the insulating substrate 10 in the active matrix substrate 36.

The gate insulating film 15 is formed to cover the insulating substrate 10, the gate wiring 11 including the gate electrode 11a and the capacitance wiring 13. At the portion of the gate insulating film 15 corresponding to the gate electrode 11a, the semiconductor film 16 and the n⁺ film 17 are formed in this order. The interlayer insulating film 14 is formed to cover the gate insulating film 15. At the portions of the interlayer insulating film 14 corresponding to the gate electrode 11a and the capacitance wiring 13, a contact hole Ca and a contact hole Cb are formed.

According to the present embodiment, when patterning after forming the film 14a containing the SOG material with photosensitivity, the resist applying process, the etching process and the resist removing process are not required, which can lower the cost of manufacturing. As the etching process is eliminated, no by-product is generated and no leak between wirings is generated, which lowers the occurrence of a failure and increases the yield.

The interlayer insulating film 14 has a transmittance of 90% or higher, and thus the display panel 3 has a preferable transmittance.

### Embodiment 4

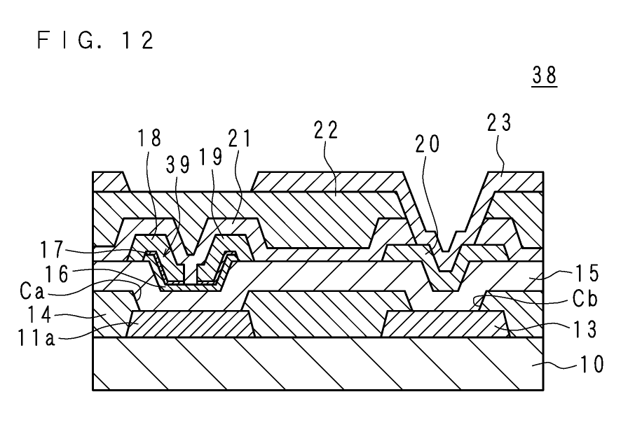

The display apparatus according to Embodiment 4 of the present invention has the same configuration as that of the display module 2 according to Embodiment 1, except that the material of the interlayer insulating film 22 of an active matrix substrate 38 is made of an SOG material with photosensitivity similar to that of the interlayer insulating film 14. FIG. 12 is a schematic section view illustrating a portion of the active matrix substrate 38 where a TFT 39 is formed. In the active matrix substrate 38, the portion where the gate wiring 11 and the source wiring 12 cross each other has the same configuration as the configuration of the portion where the gate wiring 11 and the source wiring 12 cross each other according to Embodiment 1. In FIG. 12, the same portions as those in FIG. 4 are denoted by the same reference codes and will not be described in detail.

As described above, the interlayer insulating film 22 is made of an SOG material having photosensitivity similar to that of the interlayer insulating film 14, not of acrylic resin.

According to the present embodiment, therefore, the material of the film forming the active matrix substrate 38 and the equipment for film deposition may be commonalized, which can reduce the cost of manufacturing and facilitate the management of material.

### Embodiment 5

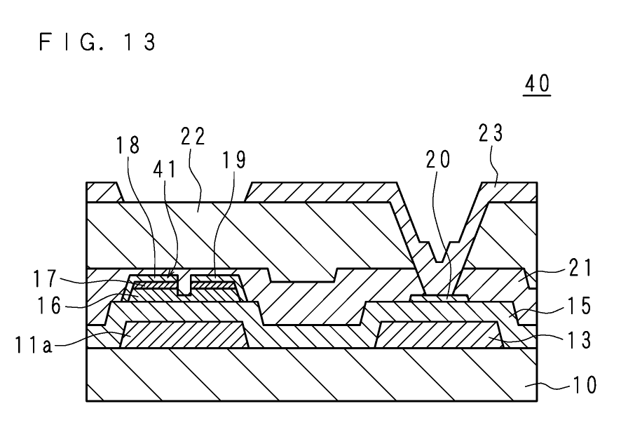

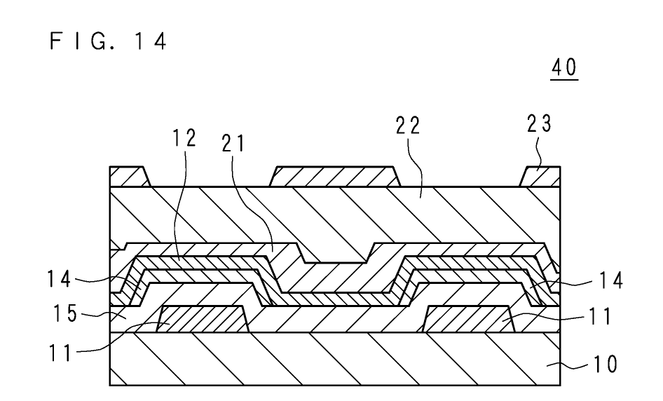

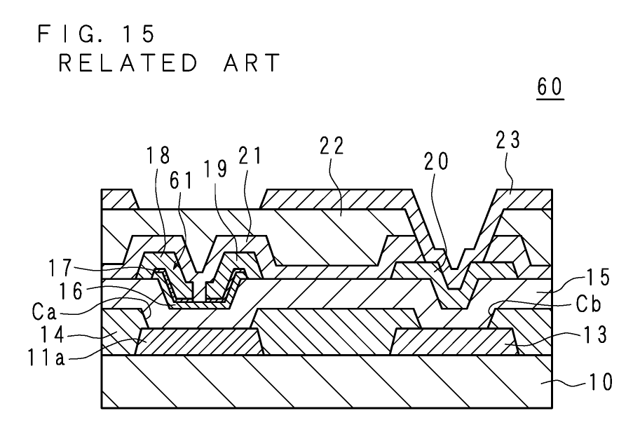

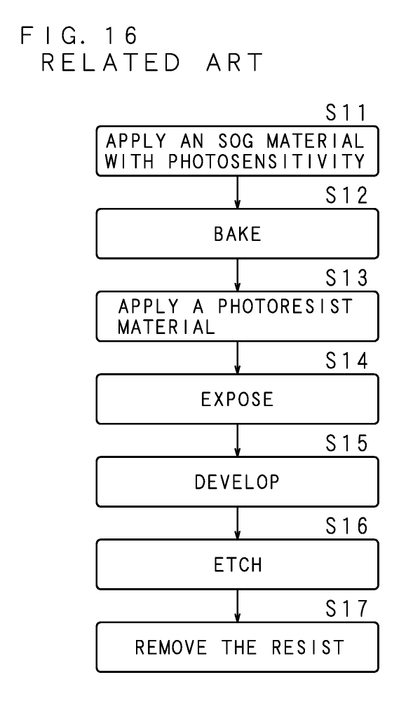

The display apparatus according to Embodiment 5 of the present invention has a configuration similar to that of the display apparatus according to Embodiment 2, except for the different deposition pattern of the interlayer insulating film 14 on an active matrix substrate 40. FIG. 13 is a schematic section view illustrating a portion of the active matrix substrate 40 where a TFT 41 is formed, and FIG. 14 is a schematic section view illustrating a portion of the active matrix substrate 40 where the gate wiring 11 and the source wiring 12 cross each other. In FIGS. 13 and 14, the same portions as those in FIGS. 9 and 10 are denoted by the same reference codes and will not be described in detail.

As illustrated in FIG. 14, at the crossing part of the gate wiring 11 and the source wiring 12 on the active matrix substrate 40, the gate insulating film 15 and the interlayer insulating film 14 are interposed in this order from the insulating substrate 10 side between the gate wiring 11 and the source wiring 12 formed on the insulating substrate 10.

The interlayer insulating film 14 is made of an SOG material having photosensitivity similar to that described above.

On the active matrix substrate 40, unlike the active matrix substrate 34 according to Embodiment 2, the interlayer insulating film 14 is not formed on the gate insulating film 15 corresponding to the portion between the gate wirings 11 and 11. Furthermore, as will be described later, the interlayer insulating film 14 is not formed over the portion where the gate electrode 11a of the gate wiring 11 is formed.

As illustrated in FIG. 13, the gate electrode 11a and the capacitance wiring 13 are formed on the insulating substrate 10 in the active matrix substrate 40.

As described above, the interlayer insulating film 14 is not formed over the portion where the gate electrode 11a of the gate wiring 11 is formed. Furthermore, the interlayer insulating film 14 is not formed over the capacitance wiring 13 as well as between the gate wiring 11 and the capacitance wiring 13.

According to the method of manufacturing an active matrix substrate in the embodiment of the present invention, as an interlayer insulating film 14 may be formed without the etching process, no abnormal substance is generated from the SOG material and the occurrence of a leak between wirings may be suppressed, so that an interlayer insulating film 14 may be formed only at a minimal part that requires lowering of the wiring capacitance at the crossing part of the gate wiring 11 and the source wiring 12. Therefore, the active matrix substrate 40 may be so designed that no interlayer insulating film 14 is disposed at a pixel portion where the transmittance needs to be secured, at a portion of the capacitance wiring 13 where the capacitance needs to be increased and at the portions of the contact holes Ca and Cb, thereby allowing the display panel 3 provided with the active matrix substrate 40 to have a preferable transmittance.

It is to be noted that, as used herein and in the appended claims, the singular forms “a”, “an”, and “the” include plural referents unless the context clearly dictates otherwise.

It should be noted that the present invention is not limited to Embodiments 1 to 5 described above, but various changes that fall within metes and bounds of the claims may also be applied. In other words, an embodiment obtained by combining technical means appropriately modified within the scope of the claims may be embraced as the technical scope of the present invention.

1-8. (canceled)

9. An active matrix substrate in which, on a substrate, a plurality of source wirings and a plurality of gate wirings are formed to cross each other in different levels, a thin-film transistor is formed near a portion where the source wiring and the gate wiring cross each other, a pixel electrode is formed which is electrically connected to a corresponding one of the source wirings via the thin-film transistor, and an interlayer insulating film containing a spin-on-glass (SOG) material is interposed at least between the source wiring and the gate wiring, wherein
the SOG material is photosensitive.

10. The active matrix substrate according to claim 9, wherein the interlayer insulating film has a resistance to heat of 350° C. or higher, a light transmittance of 90% or higher, and a dielectric constant of 4 or lower.

11. The active matrix substrate according to claim 9, wherein the interlayer insulating film is formed at a portion where the source wiring and the gate wiring cross each other.

12. The active matrix substrate according to claim 10, wherein the interlayer insulating film is formed at a portion where the source wiring and the gate wiring cross each other.

13. The active matrix substrate according to claim 9, further comprising an interlayer insulating film containing an SOG material with sensitivity over the thin-film transistor.

14. The active matrix substrate according to claim 10, further comprising an interlayer insulating film containing an SOG material with sensitivity over the thin-film transistor.

15. The active matrix substrate according to claim 11, further comprising an interlayer insulating film containing an SOG material with sensitivity over the thin-film transistor.

16. The active matrix substrate according to claim 12, further comprising an interlayer insulating film containing an SOG material with sensitivity over the thin-film transistor.

17. A display apparatus, comprising:
the active matrix substrate according to claim 9;
a display medium layer arranged on the active matrix substrate; and
an opposing substrate opposed to the active matrix substrate via the display medium layer.

18. A display apparatus, comprising:
the active matrix substrate according to claim 10;
a display medium layer arranged on the active matrix substrate; and
an opposing substrate opposed to the active matrix substrate via the display medium layer.

19. A display apparatus, comprising:
the active matrix substrate according to claim 11;
a display medium layer arranged on the active matrix substrate; and
an opposing substrate opposed to the active matrix substrate via the display medium layer.

20. A display apparatus, comprising:
the active matrix substrate according to claim 12;
a display medium layer arranged on the active matrix substrate; and
an opposing substrate opposed to the active matrix substrate via the display medium layer.

21. A display apparatus, comprising:
the active matrix substrate according to claim 13;
a display medium layer arranged on the active matrix substrate; and
an opposing substrate opposed to the active matrix substrate via the display medium layer.

22. A display apparatus, comprising:
the active matrix substrate according to claim 14;
a display medium layer arranged on the active matrix substrate; and
an opposing substrate opposed to the active matrix substrate via the display medium layer.

23. A display apparatus, comprising:
the active matrix substrate according to claim 15;
a display medium layer arranged on the active matrix substrate; and
an opposing substrate opposed to the active matrix substrate via the display medium layer.

24. A display apparatus, comprising:
the active matrix substrate according to claim 16;
a display medium layer arranged on the active matrix substrate; and
an opposing substrate opposed to the active matrix substrate via the display medium layer.

25. A method of manufacturing an active matrix substrate comprising processes of, on a substrate, forming a plurality of source wirings and a plurality of gate wirings to cross each other in different levels, forming a thin-film transistor near a portion where the source wiring and the gate wiring cross each other and forming a pixel electrode which is electrically connected to a corresponding one of the source wirings via the thin-film transistor, and comprising an interlayer insulating film forming process of forming an interlayer insulating film containing a spin-on-glass (SOG) material at least between the source wiring and the gate wiring, wherein
the interlayer insulating film forming process includes:
a film forming process of forming a film using an SOG material with photosensitivity;
a process of prebaking a formed film;
a process of exposing a prebaked film to light;
a process of developing an exposed film; and
a process of baking a developed film.

26. The method of manufacturing an active matrix substrate according to claim 25, wherein the film forming process includes forming a film at a portion where the source wiring and the gate wiring cross each other.

27. The method of manufacturing an active matrix substrate according to claim 25, wherein the SOG material contains at least two kinds of polysiloxanes with different rates of solubility to tetramethylammonium hydroxide (TMAH) water solution, a diazonaphthoquinone derivative and a solvent.

28. The method of manufacturing an active matrix substrate according to claim 26, wherein the SOG material contains at least two kinds of polysiloxanes with different rates of solubility to tetramethylammonium hydroxide (TMAH) water solution, a diazonaphthoquinone derivative and a solvent.
